(19) United States
(12) Patent Application Publication
(10) Pub. No.: US 2023/0116833 A1
(43) Pub. Date: Apr. 13, 2023

(54) MOBILE, SELF-CONTAINED, INTEGRATED MANAGEMENT AND TRANSACTION FACILITY AND METHOD OF USE OF SAME TO DEVELOP, MANAGE, AND USE CAPITAL

(71) Applicant: Lauri Edwina Elliott, Raleigh, NC (US)

(72) Inventor: Lauri Edwina Elliott, Raleigh, NC (US)

(73) Assignee: Lauri Edwina Elliott, Raleigh, NC (US)

(21) Appl. No.: 17/939,416

(22) Filed: Sep. 7, 2022

Related U.S. Application Data
(63) Continuation-in-part of application No. 17/552,411, filed on Dec. 16, 2021.
(60) Provisional application No. 63/241,419, filed on Sep. 7, 2021.

(51) Int. Cl. H05K 7/14

(52) U.S. Cl. CPC H05K 7/1497; H05K 7/1492; H05K 7/1498

(57) ABSTRACT

A mobile, extendable, self-contained, integrated assessment, management, and transaction facility that is completely equipped to assess, manage, and trade capital from almost anywhere in the world, in an example embodiment housed in a cabinet carried in a vehicle bed, in a trailer, heavy duty cart, or other mobile infrastructure that enables the facility to be mobile or portable. A mobile, extendable, self-contained capital assessment, management, and transaction facility and method of use of same to develop, manage, and use capital generally consists of a self-contained, integrated facility; mobile operation; and a method flow for capital that enables the inventory, procurement, assessment, valuation, monitoring, trading, leveraging, tracking and tracing, and other activities or tasks on or associated with different forms, or types, of tangible and intangible capital.

### CROSS-REFERENCES TO RELATED PATENT APPLICATIONS

The present application claims benefit of the U.S. Provisional patent application Ser. No. 63/241,419 filed Sep. 7, 2021 and is a continuation in part of the U.S. patent application Ser. No. 17/552,411 filed Dec. 16, 2021, which claims the benefit of U.S. Provisional patent application Ser. No. 63/126,477 filed Dec. 16, 2020, which are incorporated herein by reference in its entirety for all purposes.

### BACKGROUND

### Technical Field

The invention presented herein is generally directed towards assessing, managing, and transacting upon capital, and more specifically it relates to a mobile, extendable, self-contained, integrated facility, housed in a cabinet carried in a vehicle bed, in a trailer, heavy-duty cart, or other mobile infrastructure that enables the facility to be mobile or portable and operate almost anywhere—on land, underground, underwater, in the air, in space, and other locations. More particularly, but not limited to, the mobile, extendable, self-contained, integrated facility enables the inventory, procurement, assessment, trade, leverage, pooling, management, and tracking and tracing of different forms, or types, of capital, including but not limited to natural, human (e.g., physical, mental, spiritual), social, physical, built-environment, intellectual, and produced capital. The present invention may also perform other activities and tasks for or associated with a variety of forms, types, or combinations of capital.

### Description of the Related Art

Typically, capital is defined as “wealth in the form of money or other assets owned by a person or organization or available or contributed for a particular purpose such as starting a company or investing.” Capital also infers some form of stored value whether intrinsic or extrinsic. Capital and asset are terms that may be used interchangeably in different contexts or environments. Therefore, any reference to capital herein also pertains to assets.

Capital underlies human society economically, socially, and in other ways. The underlying value of different capital is the basis for value and economic exchange. Capital, in all its forms, can empower individuals, families, communities, and countries if it is properly assessed, managed, developed, and leveraged. Society's understanding of various forms, or types, of capital, their characteristics and attributes, their utility and value, and how to measure and evaluate them continue to evolve supported by technology and knowledge. However, this process is severely hampered in remote places, or places where there is a lack of infrastructure.

Take one form, or type, of capital—natural capital—to illustrate the current state. Natural capital is defined as a stock of natural resources. Natural capital is recognized as one of the major building blocks for society and unsustainable use of it means challenges for society. Both issues have prompted solutions based on technology, such as digital platforms, blockchain, and satellite monitoring.

The use of satellites and large body vehicles, such as airplanes, have been the means by which large amounts of data are acquired over large geographic areas. Data acquired varies from imagery to geophysical data. Fidelity is continually improving. This data is used to remotely monitor and manage capital to some degree from generally a great distance.

Other tools like digital platforms have taken data, organized it, and made it accessible to virtually anyone through the Internet. Digital platforms have taken additional measures to acquire data closer to the ground and in closer detail, such as using cars to capture GPS coordinates, physical transport routes, and images of physical objects. Now, a person may use an interactive digital map instead of a print map to navigate to a location.

Applications like geographic information systems software, as with digital platforms, are translating discrete, abundant data into usable and manageable forms of information. Analytic tools transform data and information into insights and actions. Advances in big data organization and management, artificial intelligence, automation, and other technologies will expand the usefulness, speed, seamlessness, and ease of using data in practical and everyday uses. Other technologies, such as drones, the Internet of Things, blockchain, 5G, and others, are contributing to the acquisition of more data in a larger range of perspectives and higher fidelity.

Broadly, there is more reliance on remote technologies instead of an integrated approach that combines remote technologies with ground truth and the implementation of suitable operations for remote areas, such as a mobile operation, that can enable an integrated approach to assessing, managing, and transacting upon capital almost anywhere. Therefore, there remains a gap in the ability to manage natural capital and obtain high-fidelity data in abundance in remote areas and in those areas that lack infrastructure.

There are different specific applications for tracking and transacting natural capital in remote areas, such as the one Noyes, C. invented—a transportable, self-contained assay facility with a method for use of same to procure and assay precious metals (US Patent—U.S. Pat. No. 9,005,525B2). However, many other activities are involved with properly leveraging capital, which can be integrated including but not limited to: inventory, procurement, assessment, valuation, management, and tracking and tracing. The limitations of inventions addressing this field are not limited to natural capital but are characteristic of other forms of capital and the combination of different forms of capital in unique value configurations. While this is a significant gap in remote areas or areas with a lack of infrastructure, it also holds true for some environments that are well populated and have good infrastructure.

This specification recognizes that there is a need for a mobile, extendable, self-contained, integrated assessment, management, and transaction facility and method of use of same to develop, manage, and use any form, or type, of capital.

Thus, in view of the above, there is a long-felt need in the industry to address the aforementioned deficiencies and inadequacies.

### SUMMARY

A self-contained, integrated facility is provided, as shown in and/or described in connection with at least one of the figures.

One aspect of the present disclosure relates to a mobile, extendable, self-contained, integrated assessment, management, and transaction facility and method of use of same to develop, manage, and use any form, or type, of capital. This example embodiment of the present invention is housed in a fabricated cabinet structure carried in or on a pick-up truck or other mobile structure. An example embodiment of the present invention so placed may be mobile or portable and operate on land, underwater, in the air, in space, and other locations. The present invention consists of but is not limited to: a self-contained, integrated facility, a mobile operation, and a method flow for capital. The present invention can inventory, procure, assess, valuate, monitor, trade, leverage, manage, track and trace, and perform other activities for, on, or associated with different forms, or types, of tangible and intangible capital, as well as support and conduct other tasks, functions, and activities that may or not be connected to the capital, such as assist in disaster recovery by serving as a mobile communications center.

There have thus been outlined, rather broadly, some of the features of a mobile, extendable, self-contained, integrated assessment, management, and transaction facility and method of using same to develop, manage, and use any form, or type, of capital so that the detailed description thereof may be better understood, and so that the present contribution to the art may be better appreciated. There are additional features of a mobile, extendable, self-contained, integrated assessment, management, and transaction facility and method of use of same to develop, manage, and use any form, or type, of capital that will be described hereinafter and that will form the subject matter of the claims appended hereto. In this respect, before explaining at least one embodiment of a mobile, extendable, self-contained, integrated assessment, management, and transaction facility and method of use of same to develop, manage, and use any form, or type, of capital in detail, it is to be understood that a mobile, extendable, self-contained, integrated assessment, management, and transaction facility and method of use of same to develop, manage, and use any form, or type, of capital, is not limited in its application to the details of construction or the arrangements of the components outlined in the following description or illustrated in the drawings. A mobile, extendable, self-contained, integrated assessment, management, and transaction facility and method of use of same to develop, manage, and use any form, or type, of capital, is capable of other embodiments and of being practiced and carried out in various ways. Also, it is to be understood that the phraseology and terminology employed herein are for the description and should not be regarded as limiting.

One objective is to provide a mobile, extendable, self-contained, integrated assessment, management, and transaction facility and method of use of same to develop, manage, and use any form, or type, of capital.

Another objective is to provide a mobile, extendable, self-contained, integrated assessment, management, and transaction facility and method of use of same to develop, manage, and use any form, or type, of capital that provides a secure, cohesive, durable, and transparent operation.

Another objective is to provide a mobile, extendable, self-contained, integrated assessment, management, and transaction facility and method of use of same to develop, manage, and use any form, or type, of capital that provides a provenance, tracking, and tracing system that originates at or near the source of capital and enables tracking and tracing capital, or a derivation, from the source of capital, at any point, or interval through to end users at any time.

Another objective is to provide a mobile, extendable, self-contained, integrated assessment, management, and transaction facility and method of use of same to develop, manage, and use any form, or type, of capital that provides a platform to leverage the value, features, or functions of capital without trading it in a variety of transactions, projects, and activities.

Another objective is to provide a mobile, extendable, self-contained, integrated assessment, management, and transaction facility and method of use of same to develop, manage, and use any form, or type, of capital that provides an integrated means of physically and virtually managing and monitoring capital assets.

Another objective is to provide a mobile, extendable, self-contained, integrated assessment, management, and transaction facility and method of use of same to develop, manage, and use any form, or type, of capital that includes infrastructure for on-grid and off-grid operation.

Another objective is to provide a mobile, extendable, self-contained, integrated assessment, management, and transaction facility and method of use of same to develop, manage, and use any form, or type, of capital that includes a platform for capital transactions and activities, which may be accessed and used by users from anywhere in the world synchronously or asynchronously.

Another objective is to provide a mobile, extendable, self-contained, integrated assessment, management, and transaction facility and method of use of same to develop, manage, and use any form, or type, of capital that enables an instance of capital to be pooled with other instances of capital to form unique asset pools that may be used for a variety of activities and transactions, such as securitization instruments for financial transactions.

Another objective is to provide a mobile, extendable, self-contained, integrated assessment, management, and transaction facility and method of use of same to develop, manage, and use any form, or type, of capital that enables users to monitor and manage their preservation, development, risk management, and use of capital from its source through a supply chain and to end users, and through other network or value chain configurations.

Another objective is to provide a mobile, extendable, self-contained, integrated assessment, management, and transaction facility and method of use of same to develop, manage, and use any form, or type, of capital that may be removed from and interchanged between mobile infrastructures, such as removing a mobile facility from a vehicle bed and moving it to a cart or vice versa.

Another objective is to provide a mobile, extendable, self-contained, integrated assessment, management, and transaction facility and method of use of same to develop, manage, and use any form, or type, of capital that serves up, extends, and augments the geographic scope, capacity, and capabilities of a variety of operations, using a distributed data ecosystem and other configurations or components of the present invention synchronously or asynchronously.

Another objective is to provide a mobile, extendable, self-contained, integrated assessment, management, and transaction facility and method of use of same to develop, manage, and use any form, or type, of capital that allows for space, such as the interior space of different compartments, to be re-allocated or re-configured based on tools and equipment needed, activities to be performed, and other criteria for a particular mobile operation or other operations, functions, or purposes.

Another objective is to provide a mobile, extendable, self-contained, integrated assessment, management, and transaction facility and method of use of same to develop, manage, and use any form, or type, of capital that supports other mobile operations and other types of operations, functions, purposes, and activities, such as mineral exploration, construction on remote sites, and emergency services.

One aspect of the present disclosure relates to a self-contained, integrated facility that includes a mobile facility, and a fabricated cabinet structure. The mobile facility develops, manages, and uses one or more forms of a capital in an arrangement that provides a mobile operation. The mobile facility operates in the fabricated cabinet structure. The fabricated cabinet structure includes a general storage compartment, communication and electronics compartment, a removable roof rack, a rooftop solar array, and a central compartment. The removable roof rack includes a lighting system and a video surveillance system at each corner of the removable roof rack. The lighting system and the video surveillance system are attached to the fabricated cabinet structure sitting in or on a mobile structure to provide a 360-degree view of the area surrounding the fabricated cabinet structure, the mobile structure, an under extended roll-out canopies, and a pop-up enclosure. The lighting system and the video surveillance system enable the securing and tracking of mobile operations. The rooftop solar array acts as a lid to the general storage compartment and is operable to be opened at an angle to receive solar rays. The central compartment includes a pull-out counter to conduct a plurality of activities. The pull-out counter is present on a slide rack system that enables the pull-out counter to extend behind the fabricated cabinet structure.

In an embodiment, the mobile facility includes an interior that is outfitted with a power and electrical infrastructure to enable consistent, and surge, power, and electrical capacity in one or more of an off-grid, an on-grid, and a combination environment.

In an embodiment, the mobile facility is outfitted with communication equipment, computing equipment, and data equipment to enable the mobile facility to operate whether the mobile facility is connected to a wider network or a network of the mobile facility.

In an embodiment, the mobile facility includes a pop-up/pop-out infrastructure that is activated when the mobile facility is in operation.

In an embodiment, the pop-up/pop-out infrastructure comprises one or more roll-out canopies to protect from an external physical environment.

In an embodiment, the pop-up enclosures protect from the external physical environment and provide privacy.

In an embodiment, the pop-up enclosures enclose a portable air exhaust system to remove excess heat, fumes, and dust from the pop-up enclosures.

In an embodiment, the pop-up enclosures enclose a privacy mesh to allow privacy during transactions is placed over openings of a pop-up enclosure to obscure movement and activity inside it.

In an embodiment, the privacy mesh is placed over openings of the pop-up enclosure to obscure movement and activity inside the pop-up enclosure.

In an embodiment, the pop-up enclosures enclose a portable HVAC to maintain a suitable environment for one or more operators and equipment.

In an embodiment, the pull-out counter extends from the central compartment through one or more open rear cabinet doors and an open tailgate.

In an embodiment, the communication and electronics compartment operates synchronously for continuously connected environments whether in a local and distributed data ecosystem or other network infrastructure, or operates asynchronously for non-continuous connected environments.

In an embodiment, the capital comprises tangible capital; and intangible capital.

In an embodiment, the pull-out counter conducts a plurality of activities comprising transactions, sampling, and other activities.

In an embodiment, the mobile operation functions as or as a part of a distributed data ecosystem.

These features and advantages of the present disclosure may be appreciated by reviewing the following description of the present disclosure, along with the accompanying figures wherein like reference numerals refer to like parts.

### BRIEF DESCRIPTION OF THE DRAWINGS

The accompanying drawings illustrate the embodiments of systems, methods, and other aspects of the disclosure. Any person with ordinary skills in the art will appreciate that the illustrated element boundaries (e.g., boxes, groups of boxes, or other shapes) in the figures represent an example of the boundaries. In some examples, one element may be designed as multiple elements, or multiple elements may be designed as one element. In some examples, an element shown as an internal component of one element may be implemented as an external component in another and vice versa. Furthermore, the elements may not be drawn to scale.

Various embodiments will hereinafter be described in accordance with the appended drawings, which are provided to illustrate, not limit, the scope, wherein similar designations denote similar elements, and in which:

FIG. 1 illustrates different environments in which the present invention may operate.

FIG. 2 is a side view of a pick-up truck with a mobile facility inserted into a vehicle bed, being an example embodiment of the present invention.

FIG. 3 illustrates a side view of Side A of the present invention, in accordance with one embodiment of the present invention.

FIG. 4 illustrates a side view of Side B of the present invention, in accordance with one embodiment of the present invention.

FIG. 5 illustrates a front view of the present invention, in accordance with one embodiment of the present invention.

FIG. 6 illustrates a rear view of the present invention, in accordance with one embodiment of the present invention.

FIG. 7 illustrates a top view of the present invention, in accordance with one embodiment of the present invention.

FIG. 8 illustrates a top inside view of the present invention, in accordance with one embodiment of the present invention.

FIG. 9 illustrates a top inside view with a pull-out counter, which is extended, of the present invention.

FIG. 10 illustrates a top-side view of a pull-out counter housed in a central compartment of the present invention.

FIG. 11 illustrates a top inside view of a long storage compartment configuration of the present invention, in accordance with one embodiment of the present invention.

FIG. 12 illustrates an illustration of mobile operations in the field for the present invention, in accordance with one embodiment of the present invention.

### DETAILED DESCRIPTION

The present description is best understood with reference to the detailed figures and description set forth herein. Various embodiments of the present system and method have been discussed with reference to the figures. However, those skilled in the art will readily appreciate that the detailed description provided herein with respect to the figures is merely for explanatory purposes, as the present system and method may extend beyond the described embodiments. For instance, the teachings presented and the needs of a particular application may yield multiple alternative and suitable approaches to implement the functionality of any detail of the present systems and methods described herein. Therefore, any approach to implementing the present system and method may extend beyond certain implementation choices in the following embodiments.

According to an embodiment herein, the methods of the present invention may be implemented by performing or completing manually, automatically, and/or a combination of thereof. The term “method” refers to manners, means, techniques, and procedures for accomplishing any task including, but not limited to, those manners, means, techniques, and procedures either known to the person skilled in the art or readily developed from existing manners, means, techniques and procedures by practitioners of the art to which the present invention belongs. The persons skilled in the art will envision many other possible variations within the scope of the present system and method described herein.

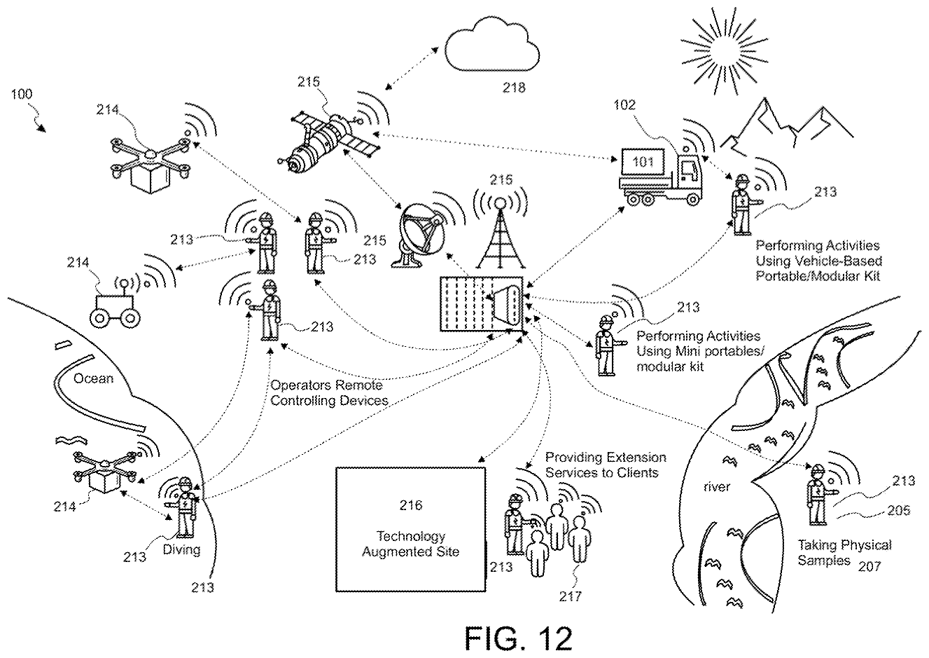

Turning now descriptively to the drawings, in which similar reference characters denote similar elements throughout the several views, the FIGS. illustrate an example embodiment comprising a self-contained, integrated facility (100) (shown in FIG. 12) that operates, or with, a mobile facility (101) (shown in FIG. 12) in a cabinet structure (103) sitting in, or on, a mobile structure (102) (shown in FIG. 12), containing an integrated capital management software (175), globally available capital transaction platform (176), and a workflow system and supporting data (177); a mobile operation (200) using a self-contained, integrated facility (100) and a method flow for capital (300) to inventory, procure, assess, valuate, monitor, trade, leverage, track and trace, and perform other activities related to any form, or type, of tangible or intangible capital while operating with or without a distributed data ecosystem (208); a method flow for capital (300); and other configurations of the original invention. such as a shipping container configuration (206).

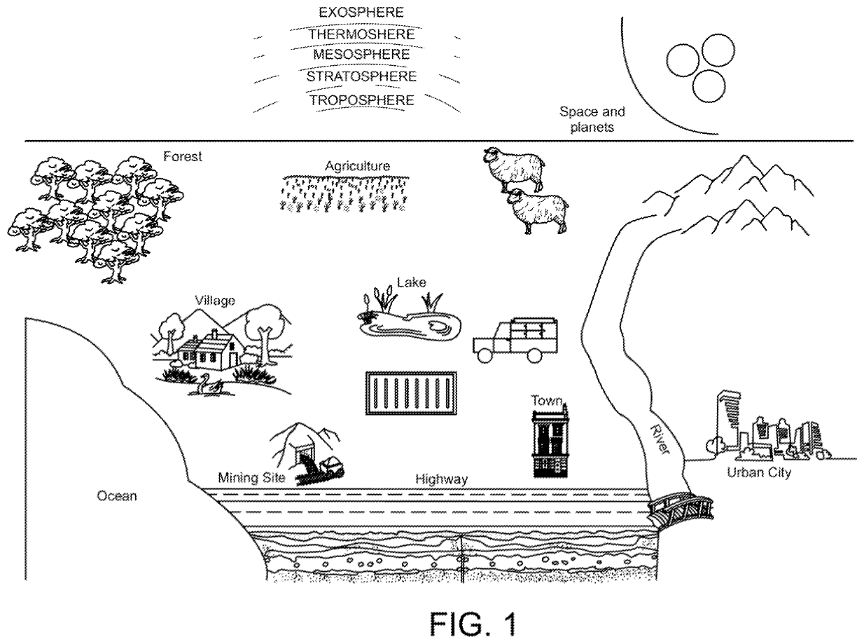

The physical manifestation of a mobile facility (101) of the example embodiment is housed in a fabricated cabinet structure (103), which sits in the bed of a vehicle or trailer; sits atop a mobile cart; or uses other types of mobile structures (102). It may operate in a variety of environments, represented in FIG. 1, with a broad range of atmospheric, climatic, and other conditions. FIG. 1 illustrates different environments in which the present invention may operate. The drawing represents the multi-configuration potential of the present invention.

Certain mechanisms are built into the present invention to ensure it is operating in the way it should, and if not, ensure that issues can be readily identified, communicated, and addressed. These mechanisms include best practices; protocols; standards like Testing and Calibration Laboratories (ISO/IEC 170250); sensors (152), meters (153), and other devices that log, monitor, and alert on conditions and events related to elements, activities, and other items in the present invention; and other mechanisms to fulfill the purpose and objectives, such as a secure and transparent operation, of the present invention.

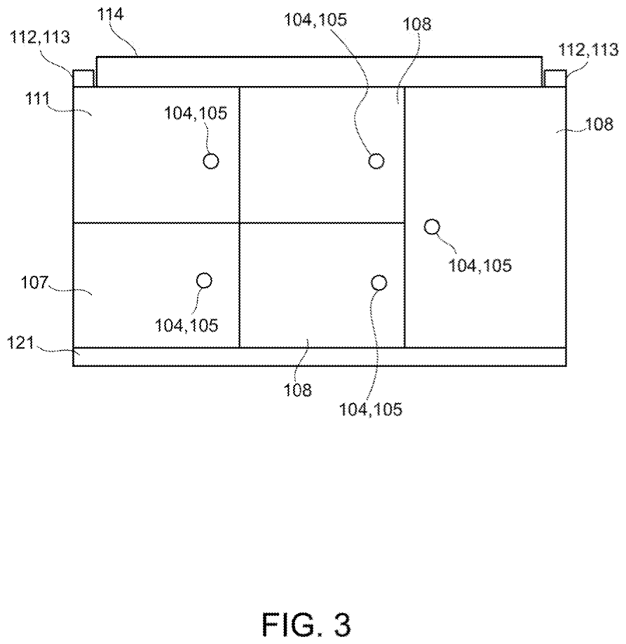

Housing the present invention in a variety of mobile structures (102) means the present invention is transportable almost anywhere—underwater, in the air, in space, on land, and in other environments. The power and electrical infrastructure (168) for the present invention may be provided onboard a mobile structure (102), such as an onboard generator in a pick-up truck (180) like a Ford F-150; embedded into a cabinet structure (103), represented in FIG. 3; traditional power systems, such as those in buildings; any combination of the aforementioned power and electrical infrastructure (168); and other types and configurations of power and electrical infrastructure (168).

The fabrication and materials of a cabinet structure (103) enable a durable operation by protecting a mobile facility (101) from and minimizing the effects of, an external, or internal, physical environment. A material, or a combination of materials, is used on the exterior of a cabinet structure (103) and interior walls (169) to minimize, eliminate, or prevent: the effect of armor piercing and small ballistic weapons; protect and control internal temperature against fire, explosions, temperatures in the physical environment and other protection- or temperature-related factors; and other types of factors. A material, or a combination of materials, that is lighter than other durable, protective materials like steel, is used to reduce the overall payload so that a cabinet structure (103) may be used in a variety of mobile structures (102) with different payload, or weight, capacity limits. A cabinet structure (103) is designed to stabilize the operating and transport environment for equipment and elements, or the items themselves, that are sensitive to movement, vibration, temperature, etc. whether a mobile structure (102), in which the cabinet structure (103) is situated, is moving or standing still.

The present invention may be adapted to operate in different environments, including in space, in earth-orbit flight, and underwater. To operate in various environments, structures, systems, and other components may be needed to protect, float, or perform other functions, so that the present invention may successfully operate. Unconventional transport modes or systems, such as a space shuttle or a rocket, may be needed to transport and deliver the present invention.

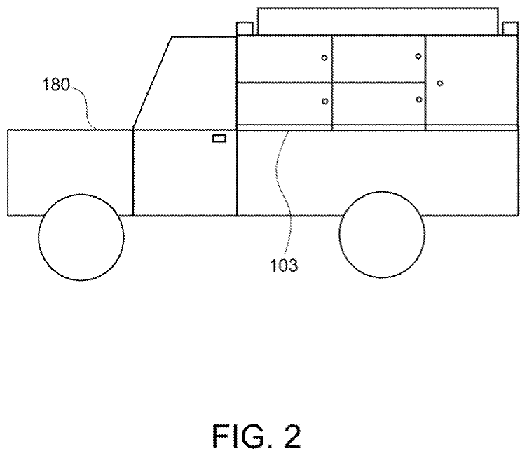

A self-contained, integrated facility (100) is represented in an example embodiment of a mobile facility (101), represented in FIGS. 2, 3, and 4, sitting in a vehicle bed (123) of a pick-up truck (180). FIG. 2 is a side view of a pick-up truck (180) with a mobile facility (101) inserted into a vehicle bed (123), being an example embodiment of the present invention. The drawing includes a representation of Side A of a cabinet structure (103) of the present invention inside a vehicle bed (123).

FIG. 3 is a side view of Side A of the present invention. The drawing is a representation of Side A, which includes a communications and electronics compartment (111), water storage compartment (107), general storage compartments (108), and a pull-out desktop (121). A cabinet structure (103) is topped with a removable roof rack (124) that consists of lighting systems (112) and video surveillance systems (113) at each end and a canister containing a roll-out canopy (114). Each cabinet door handle (104) is controlled by a cabinet door access control (105) device.

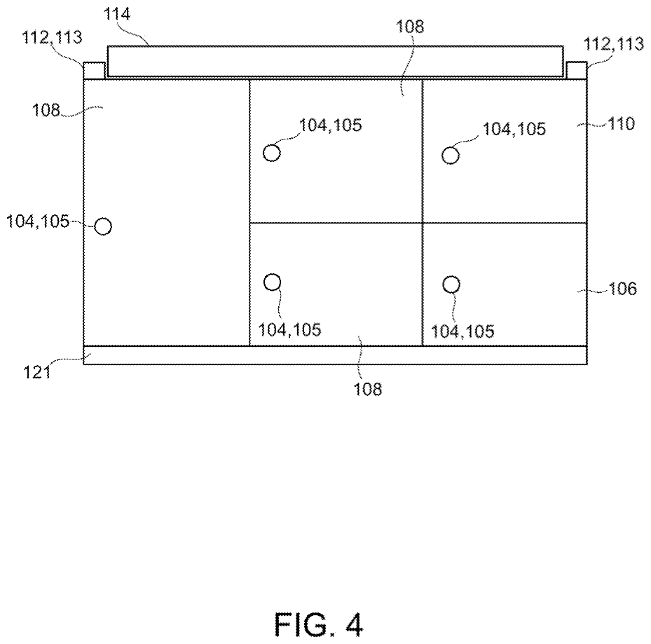

FIG. 4 is a side view of Side B of the present invention. The drawing is a representation of Side B, which contain the same elements as Side A except for a water storage compartment (107) is replaced with a fuel storage compartment (106) and a communications and electronics compartment (111) is replaced with a fuel generator compartment (110).

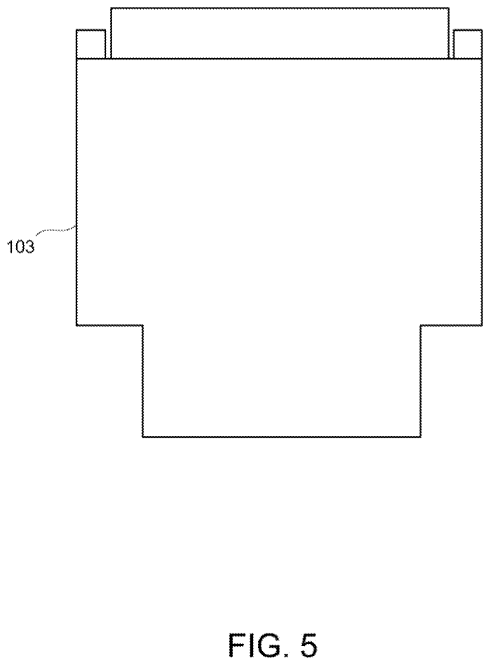

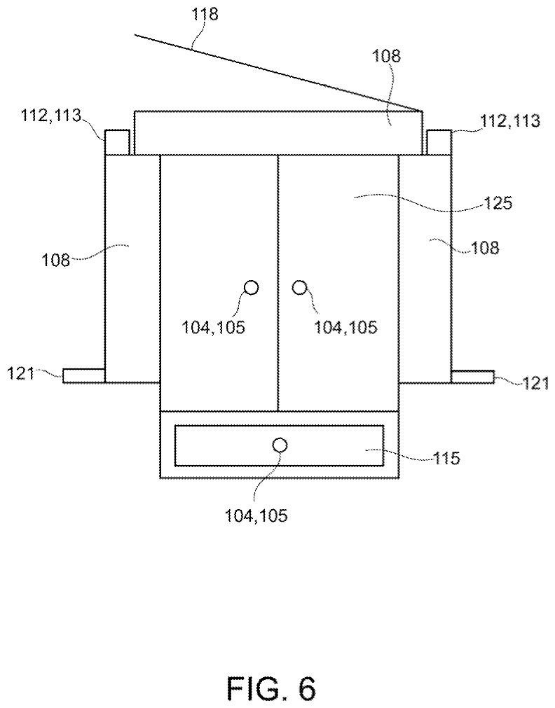

FIG. 5 is a front view of the present invention. Drawing is a representation of the front of a cabinet structure (103). The front of a cabinet structure (103) may or may not have cabinet doors (120) like the rear side, illustrated in FIG. 6, of the present invention.

FIG. 6 is a rear view of the present invention. Drawing is a representation of a rear view of a cabinet structure (103), displaying sides of general storage compartments (108), and a long storage compartment (115) that allows for different configurations of storage space inside it. The representation also displays a rear view of a removable roof rack (124), containing lighting systems (112) and video surveillance systems (113) at each end, as well as showing a rooftop solar array (118) which also serves as the lid for a general storage compartment (108) on top of a removable roof rack (124). Pull-out desktops (121) at the bottom of each general storage compartment (108) on the outside of the left and right side of a central compartment (125) are displayed. Like compartments on Side A and Side B of a cabinet structure (103), each general storage compartment (108) has a cabinet door handle (104) controlled by a cabinet door access control (105).

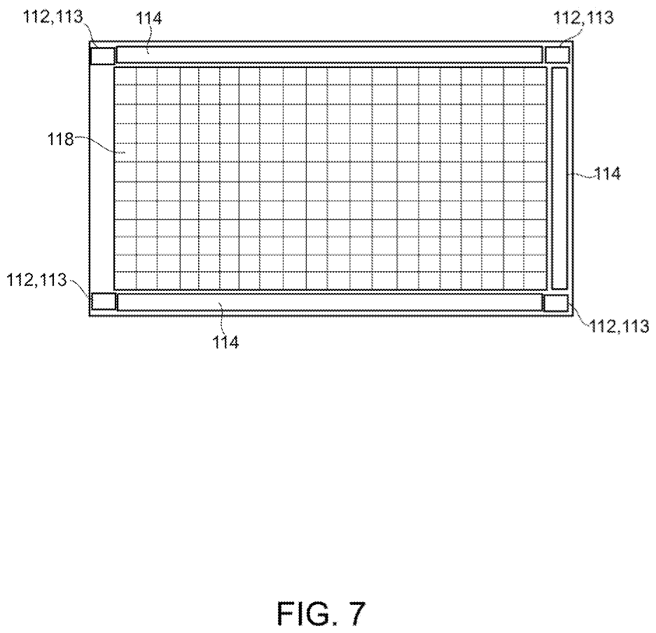

FIG. 7 is a top view of the present invention. FIG. 7 is a representation of the roof of a cabinet structure (103) with a removable roof rack (124) attached, which consists of a combination of a lighting system (112) and video surveillance system (113) at each corner, a canister containing a roll-out canopy (114) on Side A and one on Side B, and a rooftop solar array (118) positioned flat.

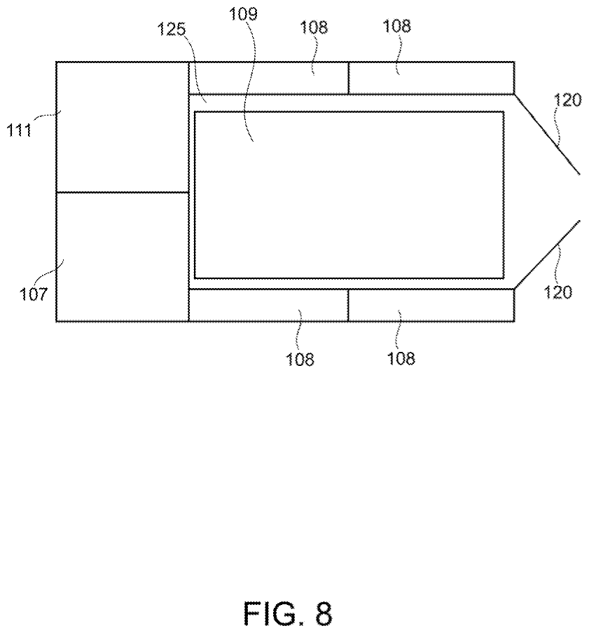

FIG. 8 is a top inside view of the present invention. Drawing is a representation of an arrangement of space in a cabinet structure (103), including a water storage compartment (107), a communications and battery compartment (111), two general storage compartments (108) on Side A and Side B, and a pull-out counter (109). The drawing also illustrates two open cabinet doors (120) at the rear of a cabinet structure (103) through which a pull-out counter (109) slides so an operator (213) operator may gain access to it.

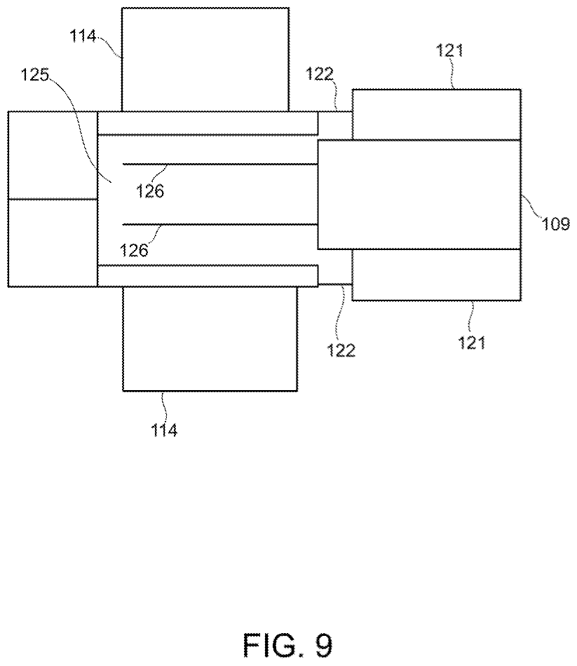

FIG. 9 is a top inside view with a pull-out counter (109), which is extended, of the present invention. FIG. 9 is a representation of when a pull-out counter (109) is extended over an open vehicle bed (123) tailgate (122), displaying a slide rack system (126), allowing for easier movement when extending or retracting a pull-out counter (109), in a central compartment (125). Pull-out desktops (121) extend from Side A and Side B of a pull-out counter (109). Roll-out canopies extend from a removable roof rack (124) (although roof rack (124) is not visible in this figure) on Side A and Side B.

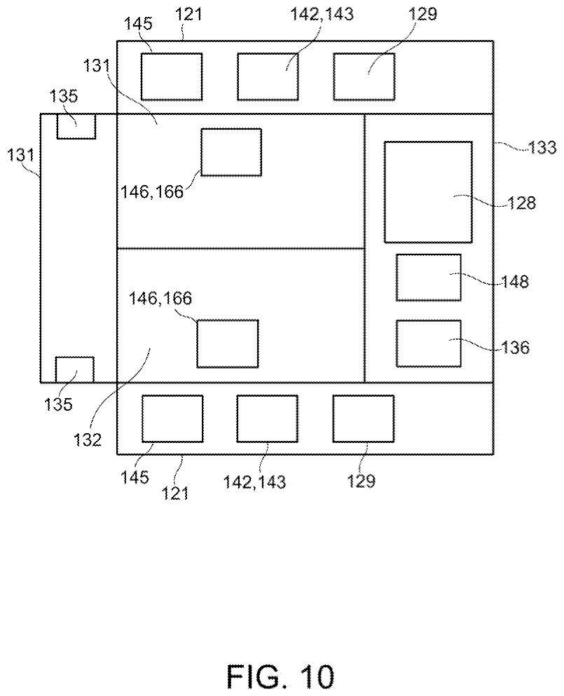

FIG. 10 is a top-side view of a pull-out counter (109) housed in a central compartment (125) of the present invention. Drawing is a representation of the work area of a pull-out counter (109). A safe (131), which has a safe drop box door (135) on two sides, is at the rear of a pull-out counter (109). The main section of a pull-out counter (109) includes an operator commercial and analysis area (132), consisting of a printer (146), a document scanner (166), and a pull-out desktop (121) on Side A and Side B. When a pull-out desktop (121) is extended, it holds a trade scale (145), a computing device (142), an input device (143), a material analysis instrument (129), and other items. A pull-out counter (109) also has a precious metals processing area (133), which consists of an induction furnace (128), an ingot processing area (148), and a sink (136) used for cooling and other purposes.

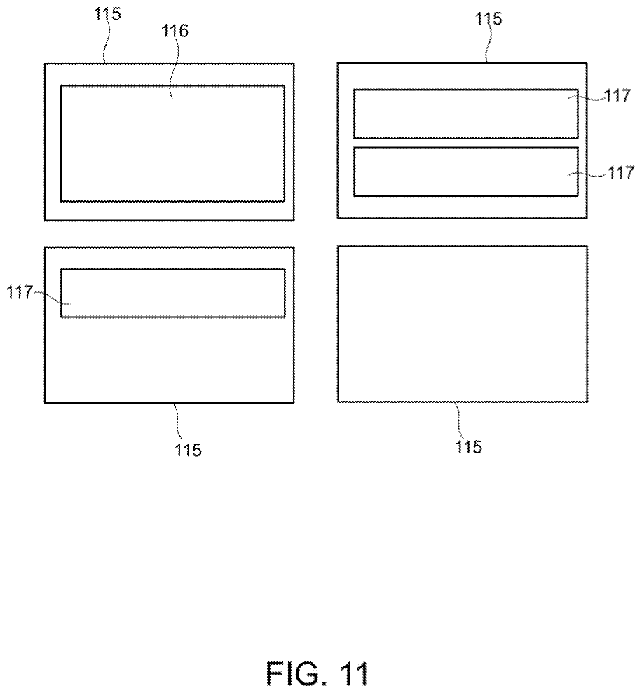

FIG. 11 is a top inside view of a long storage compartment (115) configurations of the present invention. Drawing is a representation of different configurations of a long storage compartment (115) that sits below a central compartment (125) in a cabinet structure (103). The configurations include: 1) a large removable storage tray (116), resting in a long storage compartment (115), 2) two standard removable storage trays (117), resting in a long storage compartment (115), 3) a standard removable storage tray (117) along with an open space in a long storage compartment (115), and 4) open space in a long storage compartment (115).

FIG. 12 is an illustration of mobile operations in the field for the present invention. Operators (213) conduct a variety of tasks and activities, using a variety of equipment and tools. Equipment and tools used by an operator (213) include, but are not limited to: a drone (214), a rover (204), a mobile facility (101) housed in a cabinet structure (103) loaded on a mobile structure (102), a physical investigation and sampling kit (207), and a backpack kit (205).

A mobile facility (101) is equipped to inventory, procure, assess, valuate, monitor, trade, leverage, track, and perform other functions related to different forms, types, or configurations of tangible and intangible capital in an arrangement that provides a secure and transparent mobile operation (200) whether on-grid, off-grid or other configurations. Structural, or non-structural, components of a fabricated cabinet structure (103), in which a mobile facility (101) operates, include: general storage compartments (108) on Side A, represented in FIG. 3, and Side B, represented in FIG. 4; a water storage compartment (107) on Side A, represented in FIG. 3; communications and electronics compartment (111) on Side A, represented in FIG. 3; a fuel storage compartment (106) on Side B, represented in FIG. 4; a fuel generator compartment (110) on Side B, represented in FIG. 4; a cabinet door access control (105) on each compartment on Side A, represented in FIG. 3, and on Side B, represented in FIG. 4, and at the rear of a cabinet structure (103), represented in FIG. 6; a pull-out desktop (121) on Side A, represented in FIG. 3, and on Side B, represented in FIG. 4, of a cabinet structure (103), as well on Side A and Side B of a pull-out counter (109), represented in FIG. 9; a removable roof rack (124), represented in FIG. 7, which contains a lighting system (112) and video surveillance system (113) at each corner of a removable roof rack (124), a rooftop solar array (118) that also serves as a lid to a general storage compartment (108) and can be opened at an angle to better catch solar rays, a general storage compartment (108) under a rooftop solar array (118), and a roll-out canopy (114) on each side except for the side next to the vehicle cab; a central compartment (125), represented in FIG. 8 and FIG. 9, containing a pull-out counter (109) used for conducting activities like transactions, sampling, and assessing; a pull-out counter (109) on a slide rack system (126), enabling the pull-out counter (109) to extend behind a cabinet structure (103); and a long storage compartment (115), represented in FIG. 6 and FIG. 11, with different storage configurations, including a large removable storage tray (116), two standard removable storage trays (117), a standard removable storage tray (117) along with open space, and open space. A fabricated cabinet structure (103) may have other structural, and non-structural, components, uses, configurations, etc.

Lighting systems (112) and video surveillance systems (113) are attached to a cabinet structure (103) sitting in or on a mobile structure (102) to provide a 360-degree view of the area surrounding a cabinet structure (103) and a mobile structure (102), as well as under extended roll-out canopies (114) and in pop-up enclosures (119). Lighting systems (112) and video surveillance systems (113) enable the securing and tracking of a mobile operation (200).

The interior of a mobile facility (101) is outfitted with a power and electrical infrastructure (168) that enables both consistent, and surge, power, and electrical capacity in an off-grid, an on-grid, or a combination environment, including but not limited to a fuel generator (110), inverter (155), battery power bank (127), embedded electrical outlets (154), embedded or freestanding electrical wiring (156), a wireless electrical transmission device (157), a charging station (134), and other elements.

A mobile facility (101) is outfitted with communications, computing, and data equipment that enables a mobile facility (101) to operate whether it is connected to a wider network or its own network, including but not limited to: wifi (161); a router (165); a client station (172) for an extended wireless network (209); Internet (160) access, such as through satellite systems and a mobile satellite Internet device; computing devices (142) like a laptop and a tablet; input devices (143) like a stylus, a mouse, and a bar code reader (150); personal communication devices (149) like a phone or a radio; monitoring and data collection devices like a tag (151), a sensor (152), or a meter (153) which may be wearable or embedded and have real-time or delayed transmission capability; a server (130) that houses all, or some, of the components of: an integrated capital management software (175); a globally available capital transaction platform (176); a workflow system and supporting data (177); an operational control management software (178), which controls the operational and readiness state of a mobile facility (101) and supports the integrity and health of a self-contained, integrated facility (100) and a mobile operation (200) by providing guidance, automation, etc. for a variety of tasks and activities, such as setting up a mobile operation (200) at a field site (201); other software (162), such as GIS; and other network or data devices (158). The equipment and software are capable of operating when connected or disconnected from other networks, enabling data acquisition, storage, ingestion, organization, use, analysis, and storage in a secure, transparent, and reliable manner.

A communications and electronics infrastructure (111) is designed to operate synchronously for continuously connected environments whether in a local, distributed data ecosystem (208) or other network infrastructure or to operate asynchronously for non-continuous connected environments. Due to the material composition of the communications and electronics compartment (111), the equipment is protected from the extremes of the climate, movement when the mobile structure (102) is moving, and other conditions. A communications and electronics infrastructure (111) may have different components, equipment, tools, combinations (of components, equipment, and tools), uses, functions, configurations, etc.

A mobile facility (101) has a pop-up/pop-out infrastructure (171) that is activated when a mobile facility (101) is in operation. A pop-up/pop-out infrastructure (171) provides varying levels of privacy and protection from the external physical environment, increased usability and flexibility (which enhances the agility and adaptability of the present invention), and other features and functions. A pop-up/pop-out infrastructure (171) includes, but is not limited to: roll-out canopies (114) to protect from elements above; pop-up enclosures (119) to protect from elements all around and provide privacy; a portable air exhaust system (163) to remove excess heat, fumes, and dust from enclosures; a privacy mesh (170) to allow for privacy during transactions; and a portable HVAC (144) to maintain a suitable environment for operators (213) and equipment. A pop-up/pop-out infrastructure (171) of a mobile facility (101) may have other components, equipment, tools, combinations (of components, equipment, and tools), uses, configurations, etc.

From a pull-out counter (109) that extends from a central compartment (125) through open rear cabinet doors (120) and an open tailgate (122), an operator (213) may handle activities and transactions that require more privacy, such as precious metal transactions. A pull-out counter (109) is entirely enclosed by a pop-up enclosure (119) when an operator (213) is engaging with a client (217). Components of a pull-out counter (109) include: storage and organizational space for instruments, equipment, tools, and consumables used in transactions and activities on both Side A and Side B; a printer (146) area with a printer (146), a document scanner (166), and a label printer (146) on Side A and Side B; a pull-out desktop on Side A and Side B, which serves as an operator commercial and analysis area (132) and on which an operator (213) will place a variety of tools and equipment, including but not limited to a trade scale (145), a computing device (142) with an input device (143), and a material analysis instrument (129); a precious metal processing area (133), which consists of a benchtop induction furnace (128), an ingot processing area (148), a sink (136), and a water collection/re-use/disposal system (147) connected to a sink (136; and a safe (131) with safe drop box doors (135) is located at the back of a pull-out counter (109) to store high value materials, money, and documents securely. A pull-out counter (109) may have other components, equipment, tools, combinations (of components, equipment, and tools), uses, configurations, etc.

Material analysis instruments (129), such as an XRF analyzer (139) or spectrometer (167) enable the elemental analysis, characterization, and assessment of a variety of capital, materials, and other objects. Identity and provenance systems, such as a biometric device (140) and a smart card (141 enable an operator (213) to verify people.

On the exterior of Side A and Side B of a cabinet structure (103) of a mobile facility (101), a general receiving area (127) receives a variety of capital, such as bulk agricultural commodities, which may not require a high degree of privacy. Each general receiving area (137) is covered by a roll-out canopy (114). An operator (213) may make use of a pull-out desktop (121) to perform services and activities like conducting an informal sample analysis before a trade transaction. A general receiving area (127) may have different components, equipment, tools, combinations (of components, equipment, and tools), uses, functions, configurations, etc.

Any capital, such as bulk agricultural commodities, samples, and other items that are too large to fit in a mobile facility (101) for transportation, are placed in approved temporary storage (138) with proper security and storage mechanisms, such as hermeneutic commodity bags, at a field site (201) to await transport to next destination.

A mobile facility (101) has systems, connections, and fixtures so that it may operate off-grid or connect to other systems, including but not limited to: a self-contained, integrated facility (100) housed in a shipping container configuration (206); a cluster of self-contained, integrated facilities (100) of different configurations; external power and electrical infrastructure (168), or as part of a larger system or implementation for additional capacity, flexibility, adaptability, and extensibility whether for a few hours, few days, weeks, months or years. The integrated, but self-contained, nature of a mobile facility (101) allows it to operate in isolation, distributed, synchronously, and asynchronously.

A self-contained facility (100) may have structural, functional, and operational variations. Variations may be based on a variety of factors, including purpose, objectives, context, and business model, relevant for a particular employment, or alternative embodiment, of the present invention.

The functions and capabilities of a mobile facility (101), housed in a cabinet structure (103), operate in the field, a base of operation (220), or other locations while sitting in or on a mobile structure (102), such as a pick-up truck (180). The functions, capabilities, systems, process, procedure, protocols, standards, etc. for the present invention are the same, similar, or adapted from the original invention.

A mobile operation (200) is activities performed in the field on a field site (201) where and when a mobile facility (101) has the responsibility to perform or support activities related to capital, including monitoring, managing, coordinating, cultivating, and producing. A mobile operation (200), and other configurations of the original invention, also perform activities for tangible and intangible capital even if not located at or near the location of the capital object (302), such as when selling a stored commodity to a client (217) when a client (217) is not at the location of a commodity. Activities may be performed for real-time, almost real-time, or asynchronous, execution depending on the network infrastructure currently available and conditions present.

A mobile operation (200) is illustrated in FIG. 12 where several operators (213) use a variety of equipment, such as a drone (214), and perform a variety of activities, such as training clients (217) while using the available infrastructure, including but not limited to: a mobile facility (101) housed in a cabinet structure (103) and sitting in a mobile structure (102); a distributed data ecosystem (208); a backpack kit (205); and a shipping container configuration (206) which houses a data center. Other equipment and tools included are a physical investigation or sampling kit (207), cultivation or production equipment (210), a camera (211), a measurement or assessment device (212), other network, telecommunications, or data devices (215), other augmentation or extensible equipment (219), robotics, automation, or remote control (203); precious metal devices or tools (202); and other equipment or tools. Equipment and tools used from a self-contained, integrated facility (100) may vary in form, such as hand-held or portable, to enable easier movement in the field.

As with the original invention, a mobile operation (200) at a field site (201), or other locations, may use a mobile facility (101) to access and use direct data, in addition to accessing and using indirect data, such as satellite images, to inform or execute activities related to various forms, or types, of capital; conduct mapping of, monitoring of, and managing a field site (201) and other capital; testing and implementing solutions; onboarding capital, including objects like entities; receiving and trading capital; analyzing and assessing in-ground and above-ground capital, as well as harvested or extracted capital; providing support and extension services, including training, inputs, and mentoring, to stakeholders who are involved with a field site (201); and other activities that may also occur, or do not occur, during a mobile operation (200).

A mobile operation (200) may be performed in a mobile facility (101) housed in a cabinet structure (103) sitting in or on a mobile structure (102), such as a pick-up truck (180), whether moving or standing still. A mobile facility (101) may operate in isolation, hybrid, or connected mode, which will affect which activities may be performed and capabilities executed, and how they are completed. Modes may be a mobile facility (101) connected to another mobile facility (101), or connected to other configurational facilities like a shipping container configuration (206) directly; a mobile facility (101) connected to a distributed data ecosystem (208) which may work in isolation, hybrid, or connected mode; a mobile facility (101) connected to the Internet (160), or other modes. A mobile facility (101) is designed to accommodate variation, flexibility, agility, and adaptation in mobile operation (200) over different time horizons and places.

A mobile operation (200) may work as, or as part of, a distributed data ecosystem (208). A data ecosystem is a platform used to collect, store, analyze, and leverage data and interact with the environment and people around it or connected to it. A data ecosystem may pull data from different sources and combine them to build value. A distributed data ecosystem (208) can operate at the edge of, or without connection to, global Internet infrastructure and rather provide a robust infrastructure for localized operations. A distributed data ecosystem (208) may operate in isolation, hybrid, or connected modes, as well as synchronously and asynchronously.

A distributed data ecosystem (208) provides high-speed data, communication, services, and other capabilities or offerings within its local coverage area almost continually, based on service level agreements or other arrangements, whether in isolation, hybrid, or connected mode as is with global coverage networks within their coverage areas. Depending on availability, conditions (such as cost), and other parameters, a self-contained, distributed data ecosystem (208) may connect to other networks including other distributed data ecosystems (208) and other types of networks, synchronously or asynchronously for a period of time. A distributed data ecosystem (208) may also be continuously connected to other networks, including other distributed data ecosystems (208) or other types of platforms with network infrastructure.

A distributed data ecosystem (208) consists of three components: a DDE physical infrastructure (221), a DDE data and digital infrastructure (222), and a DDE people infrastructure (223). A DDE physical infrastructure (221) operates as a self-contained, distributed data ecosystem (208) where connectivity to the Internet is not available or is inadequate; as a hybrid infrastructure for asynchronous/on-off environments including mobile transport; and as a fully connected infrastructure to the global Internet in more connected places like cities. An extended wireless network (209), covering distances of 10 km or greater, provides high-speed connectivity between devices and other distributed data ecosystem (208) components enabling fast data and communication transmission.

A network, a base station (173), a client station (172), and other physical components of a DDE physical infrastructure (221) of a distributed data ecosystem (208) may have integrated systems that allow for the dynamic registration, authorization, access, sharing, and other tasks, of different frequencies of spectrum using different technologies simultaneously, such as wifi (161), super wifi (161) (TV whitespace), and 5G cellular depending on availability of spectrum, conditions for use of, and other criteria for spectrum, resulting in the simultaneous transmission of different objects, such as energy and data. Conditions may include but are not limited to bandwidth, line of sight, authorization, and coverage parameters. A master server (130), and distributed servers (130), may be ccofigured to manage these interactions across multiple distributed data ecosystems (208). Other communications and electronics equipment and tools, power infrastructure, and other components of a DDE physical infrastructure (221) of a mobile facility (101), and other self-contained, integrated facility (100) configurations such as a shipping container configuration (206), contribute to the operation of a DDE physical infrastructure (221) of a distributed data ecosystem (208).

When power is available to a mobile facility (101), whether standing still or moving, background activities like network connections, data transfer, and system checks are completed automatically or initiated manually. At a base of operation (220), a mobile facility (101) will normally be connected continuously to the network, power, and computing infrastructure of a base of operation (220) so that predefined background tasks occur automatically. Once outside a base of operation (220), depending on a variety of parameters, such as power and network connection availability, a mobile facility (101) may only be enabled to execute a sub-set of its full capabilities, offerings, tasks, etc. The infrastructure of a distributed data ecosystem (208) allows a mobile facility (101) at any location or moving within a distributed data ecosystem's (208) coverage area to remain connected to the network and computing infrastructure of a base of operation (220). At some locations or at certain times, a mobile facility (101) may not be able to maintain a connection to the network and computing infrastructure of a base of operation (220), so a mobile facility (101) may solely rely on its onboard network, power, and computing infrastructures, such as a server (130), wifi (161) and applications and data resident on a server (130). An operational control management software (178) may manage various activities and tasks between these environments automatically or an operator (213) may initiate activities manually.

A DDE data and digital infrastructure (222) provides robust operations to generate/collect, ingest, manage, analyze, use, disseminate, and store data in a distributed, connected, or self-contained environment. An integrated capital management software (175), a globally available capital transaction platform (176), software enabled by a workflow system and supporting data (177), other software and platforms like GIS, and their underlying ‘soft’ infrastructure enable a DDE data and digital infrastructure (222) for the present invention and the original invention upon which it is based. A DDE data and digital infrastructure (222) also enables ‘intelligent’ data use with analytics, machine learning, and artificial intelligence technologies (179) that may run on top of a DDE physical infrastructure (221) and a DDE data and digital infrastructure (222) of a distributed data ecosystem (208) in self-contained, distributed, asynchronous, or connected mode.

A workflow system and supporting data (177) on a DDE data and digital infrastructure (222) of a distributed data ecosystem (208) are used to guide and support an operator (213) in completing tasks and activities while at a base of operation (220) or during a mobile operation (200). An operator (213) may conduct work, like conducting a variety of tasks through an integrated capital management software (175) and other applications, while on the move in preparation, during, and as a follow-up to activities at a particular location or locations. Only a subset of the capabilities of the present invention may be available while on the move.

A DDE people infrastructure (223) develops and deploys teams and stakeholders to manage the majority of a mobile operation (200), according to global best practices and standards, as well as innovations that transform the status quo. Operators (213), and the system that supports them, enable a DDE people infrastructure (223) component and empower the people connected to it. A variety of support mechanisms for operators (213) and stakeholders include face-to-face, on-demand, asynchronous, or remote training, mentoring, and coaching which may, or may not, be amplified with: gamification; augmented or virtual reality; other technologies, equipment, and tools; and predefined, and perhaps automated, processes, and procedures.

A mobile operation (200) empowered through a flexible and adaptive mobile facility (101), a distributed data ecosystem (208), and other components, features, and capabilities enable a mobile operation (200) to perform other functions and activities that may or may not pertain directly to capital, including disaster response and emergency services.

A mobile operation (200) may have structural, functional, and operational variations. Structures, functions, operations, and other items of a mobile operation (200) are added, adapted, or deleted as needed based on a variety of factors, including purpose, objectives, context, and business model, relevant for a particular employment, or alternative embodiment, of the present invention.

A self-contained, integrated facility (100), a mobile operation (200), and other components or configurations of the present invention or the original invention can use a method flow for capital (300) to develop, manage, or use almost any form, type, or combination of capital. A method flow for capital (300) to develop, manage, or use almost any form, type, or combination of capital is based on defining the parameters, characterizations, conditions, steps, procedures, measurements, tools, equipment, etc. needed to perform different activities on, with or associated with a particular form, type, or combination of capital. The definitions of these various variables are encapsulated in a capital-type profile template (301).

A capital type profile template (301) is categorized into major categories and sub-categories of capital, including but not limited to human capital, intellectual capital, produced capital, and social capital, to which are assigned general attributes, characteristics, appropriate measures, and methods of measuring, appropriate ways of evaluating, etc. These categories assist in structuring the operationalization of a capital-type profile template (301). A capital type profile template (301) is populated with information, such as attributes and means of measurement, for a particular form, type, or combination of capital. Once completed and approved, a capital type profile template (301) is activated.

Once a capital type profile template (302) is generated and activated, it may be used to profile a particular capital object (302). Once a particular capital object (302) is onboarded, activated, and profiled, a variety of activities, tasks, events, etc. may be performed on, with, or associated with a particular capital object (302). Based on a capital type profile template (302) applied to a particular capital object (302), different decisions, actions, tasks, and activities will be made available or activated for a particular capital object (302). Within this framework, capabilities and functions of a self-contained, integrated facility (100) or mobile operation (200) are guided for any tasks performed on or associated with a particular capital object (302), using a particular capital type profile template (301), through an integrated capital management software (175), globally available capital transaction platform (176), other software and other components.

A method flow for capital (300) may have structural, functional, and operational variations. Structures, functions, operations, and other items of a method flow for capital (300) are added, adapted, or deleted as needed based on a variety of factors, including purpose, objectives, context, and business model, relevant for a particular employment, or alternative embodiment, of the present invention.

A self-contained, integrated mobile facility (100), a mobile operation (200), and a method flow for capital (300) are the main elements of the present invention. The physical, digital, and people sub-elements of the present invention are connected through protocols, processes, procedures, workflows, software, and other components that integrate the various elements into an integrated system. The integration and connections of these elements enable a cohesive, integrated, and interoperable operation.

The present invention as a whole, or in part, may be embodied in a variety of embodiments. The present invention may be altered in a variety of ways, such as structural change, functional change, operational change, miniaturization, virtualization, full remote control, automation, robotics, self-learning, modularization, material change, device change, equipment or instrument change, and other alterations to create alternative embodiments. An example alternative embodiment may be a backpack kit (205) needed due to special requirements like more flexible mobility or navigation over terrain inaccessible to vehicles. Other alternative embodiments may derive based on a variety of factors, including contextual factors, purpose, objectives, or other factors. The present invention may be embodied in a variety of embodiments simultaneously operating in particular employment of the present invention.

Operation of Preferred Embodiment: A self-contained, integrated facility (100) housed in a cabinet structure (103) sitting in or on a vehicle bed (123) of a pick-up truck (180), a particular type of mobile structure (102), is a preferred embodiment of the present invention, which may operate with or without any combination of a distributed data ecosystem (208), a mobile operation (200), an integrated capital management software (175), a globally available capital transaction platform (176), a workflow system and supporting data (177), an operational control management software (178), and other components. This preferred embodiment, in a variety of configurations, may operate in whole, or part, either moving or standing still.

A self-contained, integrated facility (100) may have a base of operation (220), such as an office or compound at which materials, data, supplies, teams, etc. may be prepared and swapped out. A self-contained, integrated facility (100) may work away from a base of operation (220) for several hours or several days without needing to return to a base of operation (220) for re-supplying. This period may be extended if basic supplies, like fuel and Internet connectivity, may be provided sufficiently at other locations other than a base of operation (220).

An instance of a mobile operation (200), illustrated in FIG. 2, is organized based on assigned work in a workflow system and supporting data (177) with workflows of an integrated capital management software (175) embedded into it. An operator (213) plans and schedules work assignments grouped into an instance of a mobile operation (200). Based on a planned instance of a mobile operation (200), an operator (213) may prepare and stock a mobile facility (101) as needed for an instance of a mobile operation (200). Once preparation is concluded, an operator (213) may use a workflow system and supporting data (177), an operational control management software (178), and other tools, equipment, and resources to test the readiness of an instance of a mobile operation (200).

While a mobile operation (200) is in route to a location, or series of locations, a non-driving operator (213) may continue to complete work and prepare for tasks and activities that will be executed for a particular instance of a mobile operation (200): offline, connected to the network, power, and computing infrastructure of a mobile facility (101) alone, connected to a network and computing infrastructure of a distributed data ecosystem (208), or a combination of these alternatives. An operational control management system (178) will automatically control the environmental parameters, such as offline versus connected, devices, and applications in the background for an operator (213) based on different parameters, including but not limited to the location and time at which an operator (213) executes a particular activity. An operator (213) may make manual adjustments as he or she is authorized to do so.

Before conducting any mobile operation (200), an operator (213) is authenticated and authorized, using biometric multi-factor authentication or other authentication techniques. Based on authentication, as well as access and authorization rights, an operator (213) may be able to perform a variety of tasks and activities. When a mobile facility (101) comes to a standstill to support a particular instance of a mobile operation (200), an operator (213) will disembark from the cab of a pick-up truck (180). From a hand-held computing device (142) and using an input device (143), an operator (213) will initiate set-up procedures through an operational control management system (178) that prepares a mobile facility (101), illustrated in FIGS. 2, 3, 4, 5, 6, 7, 8, 9, 10, 11, for work assignments like assessing and trading capital.

Set-up procedures are a combination of automated and manual tasks that an operator (213) initiates, or conducts, and which an operational control management system (178) and a workflow system and supporting data (176) guide an operator (213) through. Set-up procedures include, but are not limited to: positioning a rooftop solar array (118) at an angle to capture sun rays and provide access to a general storage compartment (108) below it in a removable roof rack (124); turn on video surveillance systems (113) and lighting systems (112); unlock cabinet doors (120) through cabinet door access controls (105) on a cabinet structure (103); extend roll-out canopies (114); set up a pop-up enclosure (119); open a tail gate (122) and extend a pull-out counter (109) from a central compartment (125); extend pull-out desktops (121); pull out equipment and tools like an induction furnace (128), a material analysis instrument (129) such as an XRF analyzer (139), and a trade scale (145); set up a sink (136) and water collection/re-use/disposal system (147), then stock a sink's (136) tank with water from a water storage compartment (107); complete checks on systems, equipment, and tools to ensure they may be operated safely and efficiently; and other procedures.

Set-up involves making sure that a mobile operation (200) operates safely, securely, reliably, environmentally friendly, and efficiently so an operator (213) places equipment and tools in specific positions in different areas, including a precious metal processing area (133), ingot processing area (148), general receiving area, operator commercial and analysis area (132). Also, a portable HVAC (144) and a portable air exhaust system (163) are placed and started in a pop-up enclosure (119); and a privacy mesh (170) is placed over the openings of a pop-up enclosure (119) to obscure movement and activity inside it.

As an operator (213) is performing tasks and activities that use a workflow system and supporting data (177), an operational control management software (178), an integrated capital management software (175), a globally available capital transaction platform (176), or analytics, machine learning, and artificial intelligence technologies (179), an operator (213) is interacting with background operations flowing through an immediate wifi (161) network connected to a server (130) housed in a communications and electronics compartment (111) in a mobile facility (101), or through an extended wireless network (209) connected to a data center and its equipment at a base of operation (220), which could be a shipping container configuration (206), office, or compound. When at a base of operation (220), a fiber or wifi (161) connection may be used.

Activities at a mobile facility (101) may include trading, pooling, leveraging, and sampling a capital object (302). An operator (213) may also consult, coach, train, perform a demonstration for, mentor, or perform other tasks for or with a client (217). For activities involving a client (217) coming to a mobile facility (101) such as selling a commodity or taking sensor readings for preventative health checks, an operator (213) will first verify the identity of a client (217), using a hand-held biometric device (140) and a smart card (141) that a client (217) has in his or her possession. A client (217) or an operator (213) will initiate a procedure for an activity or transaction, such as selling a commodity, using an integrated capital management software (175) accessible on a computing device (142) with an input device (143).

If there is more than one operator (213) at a field site (201), more than one activity may occur simultaneously. More than one operator (213) may also work at a mobile facility (101) serving clients (217). One operator may work on each side of a cabinet structure (103), Side A and Side B as illustrated in FIGS. 3 and 4 respectively. Side A and B are used to conduct transactions on non-metal capital, such as agriculture, intellectual, and physical. One operator may work on each side of a pull-out counter (109) from the rear side of a mobile facility (101).

While working at a mobile facility (101), an operator (213) will frequently take out supplies and consumables, e.g., paper, security bag (164), sample bags, fuel, and water, from different storage areas in a mobile facility (101) including a general storage compartment (108), shown in FIG. 6, on top of a removable roof rack (124); general storage compartments (108), shown in FIGS. 3 and 4, on Side A and Side B; a communications and electronics compartment (111) and water storage compartment (107), shown in FIG. 3, on Side A; a fuel generator compartment (110) and fuel storage compartment (106), shown in FIG. 4, on Side B; a long storage compartment (115) with a large removable storage tray (116) or two standard removable storage trays (117), which are interchangeable, that is accessed from the rear of a mobile facility (101) from underneath a central compartment (125); and small general storage compartments (108) on each side of a long storage compartment (115).

Other operators (213) may work near a mobile facility (101) providing training and coaching to clients (217) or collecting data from them; flying drones (214) or driving rovers (204) remotely to view, map, monitor, and collect data at a field site; inventorying natural capital and profiling clients (217), communities, etc.; collecting samples of soil, water, plants, and other items for analysis, using a material analysis instrument (219) like an XRF analyzer (139) or a spectrometer (167), in situ, at a mobile facility (101), or other location. Operators (213) a distance from each other stay in communication, each using a personal communication device (149) like a phone, a radio, or other types of device.

When a precious metal, natural capital trade transaction is initiated by an operator (213) or a client (217), the process is: 1) A client enters a pop-up enclosure (119) covering a pull-out counter (109) extended at the rear of a mobile facility (101) and an operator (213) ensures a privacy mesh (170) is placed properly, 2) a client is biometrically authenticated, using a biometric device (140), smart card (141), and biometric credential records stored on a biometric device (140) or a server (130) accessed through an available network, 3) a transaction, such as a trade, is initiated electronically through an integrated capital management software (175) and workflow system and supporting data (177), 4) an operator (213) weighs a precious metal like gold that a client (217) wants to sell, using a counter trade scale (145) on one side of a pull-out counter (109) on a pull-out desktop (121) illustrated in FIG. 10, 5) an operator (213) takes a precious metal and melts it in an induction furnace (128) at a precious metal processing area (133), 6) once a precious metal is melted, an operator (213) takes a sample, using a pin sampler (159), 7) an operator (213) analyzes a sample of a precious metal on a pin sampler (159), using an XRF analyzer, at an operator commercial and analysis area (32), 8) the characterization data is automatically loaded into an integrated capital management software (175) to generate a quote, 9) a quote is generated and shown on a computing device so that a client (217) may review and approve, 10) if a client (217) signs a quote to accept it and sell a precious metal, an operator (213) pours a precious metal into an ingot at an ingot processing area (148), 11) a precious metal ingot is placed in a sink (136) to cool and moved to a place on a pull-out desktop (121) by an operator (213), 12) an operator (213) takes a printed label from a printer (146) that was automatically generated and printed after a client (213) accepted a quote and pulls out a security bag (164), 13) an operator (213) places a particular printed label on a security bag (164) and places a precious metal ingot inside a security bag (164) with a particular printed label, which references a particular precious metal tied to an accepted quote and initiates the type of transaction—trade, pool, leverage, or others, 14) an operator (213), scans a barcode on a security bag (164) sealed with a precious metal ingot inside, using a barcode reader (150) and places a precious metal ingot in a security bag (164) in a safe (131) through a safe drop box door (131), 15) a receipt for a particular precious metal transaction is generated by an integrated capital management software (175) and given to a client (217), either a print copy is printed and given to a client (217) or sent to a client (217) via electronic means like email or sms, and 16) a precious metal transaction is closed on an integrated capital management software (175) and a client (217) leaves a pop-up enclosure (119).

For a natural capital transaction that does not involve a precious metal, a natural capital transaction may occur on either side of a mobile facility (101), which has a general receiving area (137), or on either side of an extended, pull-out counter (109) at an operator commercial and analysis area (132). A non-precious metal transaction process is: 1) A client enters a general receiving area (127) or an operator commercial and analysis area (132), 2) a client is biometrically authenticated, using a biometric device (140), smart card (141), and biometric credential records stored on a biometric device (140) or on a server (130) accessed through an available network, 2) a transaction, such as a trade, is initiated electronically through an integrated capital management software (175) and workflow system and supporting data (177), 3) an operator (213) weighs a non-precious metal capital like cocoa that a client (217) wants to transact on, using a floor or counter trade scale (145), 4) an operator (213) takes a sample, according to protocols and routines for a particular type of natural capital in an integrated capital management software (175), 5) an operator (213) analyzes a sample of a natural capital, or a commodity, using a material analysis instrument (129), such as an XRF analyzer (139), microscope, or spectrometer (167), at an operator commercial and analysis area (132), 6) the characterization data is automatically loaded into an integrated capital management software (175) to generate a quote, 7) a quote is generated and shown on a computing device so that a client (217) may review and approve, 8) if a client (217) signs a quote to accept it and transact (e.g., trade, pool, leverage) on natural capital, or a commodity, an operator (213) places an automatically-generated, printed label on a container holding a particular natural capital object (302) involved in a particular transaction, 9) an operator (213), scans a barcode on a printed label so that a natural capital object (302) involved in a particular transaction is recorded as received, 10) a natural capital object (302) involved in a particular transaction and is received is moved to an appropriate, secure, and climate appropriate temporary storage (138) to wait for pick up by a logistics unit or, if small enough, is placed in one of the storage areas inside a mobile facility (101), 14) a receipt for a particular natural capital transaction is generated by an integrated capital management software (175) and given to a client (217), either a print copy is printed and given to a client (217) or sent to a client (217) via electronic means, and 15) a natural capital transaction is closed on an integrated capital management software (175) and a client (217) leaves the area of a mobile facility (101).

A mobile facility (101) may be used with any form, or type, of tangible or intangible capital, including human, produced capital, intellectual, and social, and using all or some of its components, to identify, inventory, assess, valuate, trade, pool, leverage, manage, monitor, etc. For any particular capital object (302) where routines, activities, tasks, etc. are performed in association with it, a capital type profile template (301) may exist. A capital type profile template (301) is a structured record, containing parameters for conducting tasks, or activities, connected to a form, or type, of capital, including name, attributes, dimensions of value and their specific attributes or indicators, methods of measuring attributes and dimensions of value, methods of valuation, uses and applications, and other data and information concerning a particular form, or type, of capital. A capital type profile template (301) is the basis on which a particular capital object (302) may be onboarded, managed, and leveraged during its life by an integrated capital management software (175), a globally available capital transaction platform (176), and other equipment and tools contained within a mobile facility (101) or elsewhere. If there is not a capital type profile template (301) available for a particular form, or type, of capital, it must be created before a particular capital object (302) may be onboarded fully.

For any transaction, activity, or task that may involve various types of intangible and intangible capital either singularly or in combinations and not illustrated previously, a transaction, activity, or task may occur on either side of a mobile facility (101), which has a general receiving area (137), on either side of an extended, pull-out counter (109) at an operator commercial and analysis area (132), or within range of a mobile facility (101) where a transaction, task, or activity may be performed successfully. A process applied to any form, or, type of capital process to complete a transaction, task, or activity is: 1) A client enters a general receiving area (127) or an operator commercial and analysis area (132), 2) a client is biometrically authenticated, using a biometric device (140), smart card (141), and biometric credential records stored on a biometric device (140) or on a server (130) accessed through an available network, 2) a transaction, such as a trade, measurement, assessment, or characterization, is initiated electronically through an integrated capital management software (175) and a workflow system and supporting data (177), 3) an operator (213) performs a transaction, task, or activity flow based on protocols and routines established in an integrated capital management software (175) and a workflow system and supporting data (177), as well as using relevant capital type profiles (301), equipment, tools, etc., 4) Upon completion of a particular transaction, task, or activity, a summary or receipt is generated and displayed on operator and client screens, 5) from a display screen, a client may send or print a summary or receipt, and 6) a transaction, task, or activity is closed out and recorded in an integrated capital management software (175).

A variety of forms, types, or combinations of tangible or intangible capital may be onboarded, assessed, managed, transacted upon, etc. either where a capital object (302) is located or remotely through a variety of methods, equipment, tools, and technologies, such as using virtual reality glasses to tour a field through the eyes of an operator (213) in either real-time or on demand. Performing a variety of tasks, activities, etc. for forms, types, or combinations of capital that are not wholly natural capital follows the same or similar conventions, protocols, procedures, processes, standards, etc. of the present invention and the original invention.

During preparation for, conducting, and closing a mobile operation (200), a mobile facility (101), its components, and other systems, equipment, and tools are continually monitored and managed, including but not limited to: when using equipment like a video surveillance system (113), a lighting system (112), and motion detectors that respond when any movement is detected when a mobile facility (101) is at a standstill; or when software (162) performs activities, tasks, or operations. Events, states, and other indicators are generated in logs in different sub-systems of a mobile facility (101), such as an integrated capital management software (175), a globally available capital transaction platform (176), a workflow system and supporting data (177), an operational control management software (178), analytics, machine learning, and artificial intelligence technologies (179), a material analysis instrument (129), a battery power bank (127), an induction furnace (128), a server (130), a safe (131), a cabinet door access control (105), a rooftop solar array (118), and other equipment, tools, instruments, and components associated with a mobile facility (101) and a mobile structure (102) in which, or on which, it is sitting, such as a pick-up truck (180).

Logs associated with a mobile operation (200) are transferred, copied, or accessed remotely from a hybrid centralized/distributed system of monitoring and management agents with or without assistance from an operator (213). Depending on network availability, topology, cost, etc., logs will reach a central operations platform where more detailed analysis, monitoring, and management may be conducted due to increased resource availability. At any point of a distributed system of monitoring and management agents, whether local on a mobile facility (101), at a server (130) at a base of operation, or at another location and according to predefined, or automatically generated, parameters, alerts may be generated and actions are taken automatically or manually, such as blocking a transaction from going further.

Data associated with a mobile operation (200) is used to adjust, adapt, refine, etc. parameters and tasks inside the system/component management function that operates in and through an integrated capital management software (175), a globally available capital transaction platform (176), a workflow system and supporting data (177), and other software infrastructure layers. A system/component management function includes monitoring, risk and security management, capital management administration, scenarios and decision support, and other management functions. In some cases, the data will automatically generate work assignments for a mobile operation (200) in the future.

When a mobile operation (200) is finished at a particular field site (201) or completed altogether, an operator (213) will close out activities and close up a mobile facility (101) in preparation for moving to another location. Similar to setting up at a field site (201), an operator (213) will use an operational management control software (178) to initiate and carry out close out/close up procedures and tasks; store equipment, tools, devices, consumables in appropriate storage areas; and complete other tasks in preparation for leaving a field site (201). When returning to a base of operation (220), certain automated tasks will execute upon a self-contained, integrated facility (100) recognizing it is within range of a base of operation (220), such as syncing all data between servers (130) in a mobile facility (101) and a base of operation (220).

Unless otherwise defined, all terms (including technical and scientific terms) used in this disclosure have the same meaning as commonly understood by one of ordinary skill in the art to which this disclosure belongs. It is to be understood that the phrases or terms employed of the present invention are for description and not for limitation. As will be appreciated by one of skill in the art, the present disclosure may be embodied as a device, system, and method, or computer program product. Further, the present invention may take the form of a computer program product on a computer-readable storage medium having computer-usable program code embodied in the medium. The present systems and methods have been described above with reference to specific examples. However, other embodiments and examples than the above description are equally possible within the scope of the present invention. The scope of the disclosure may only be limited by the appended patent claims. Even though modifications and changes may be suggested by the persons skilled in the art, it is the intention of the inventors and applicants to embody within the patent warranted hereon all the changes and modifications as reasonably and properly come within the scope of the contribution the inventors and applicants to the art. The scope of the embodiments of the present invention is ascertained with the claims to be submitted at the time of filing the complete specification.

What is claimed is:

1. A self-contained, integrated facility (100), comprises:
a mobile facility (101) to develop, manage, and use one or more forms of a capital in an arrangement that provides a mobile operation (200); and
a fabricated cabinet structure (103), wherein the mobile facility (101) operates in the fabricated cabinet structure (103), wherein the fabricated cabinet structure (103) comprises:
a general storage compartment (108);
a communication and electronics compartment (111);
a removable roof rack (124) comprising:
a lighting system (112) and a video surveillance system (113) at each corner of the removable roof rack (124), wherein the lighting system (112) and the video surveillance system (113) are attached to the fabricated cabinet structure (103) sitting in or on a mobile structure (102) to provide a 360-degree view of the area surrounding the fabricated cabinet structure (103), the mobile structure (102), an under extended roll-out canopies (114) and a pop-up enclosure (119), wherein the lighting systems (112) and the video surveillance systems (113) enable the securing and tracking of the mobile operation (200);
a rooftop solar array (118) acts as a lid to the general storage compartment (108) and is operable to be opened at an angle to receive solar rays; and
a central compartment (125) comprising: a pull-out counter (109) to conduct a plurality of activities, wherein the pull-out counter (109) is present on a slide rack system (126) that enables the pull-out counter (109) to extend behind the fabricated cabinet structure (103).

2. The self-contained, integrated facility (100) as claimed in claim 1, wherein the mobile facility (101) includes an interior that is outfitted with a power and electrical infrastructure (168) to enable consistent, and surge, power, and electrical capacity in one or more of an off-grid, an on-grid, and a combination environment.

3. The self-contained, integrated facility (100) as claimed in claim 1, wherein the mobile facility (101) is outfitted with communication equipment, computing equipment, and data equipment to enable the mobile facility (101) to operate whether the mobile facility (101) is connected to a wider network or a network of the mobile facility (101).

4. The self-contained, integrated facility (100) as claimed in claim 1, wherein the mobile facility (101) includes a pop-up/pop-out infrastructure (171) that is activated when the mobile facility (101) is in operation.

5. The self-contained, integrated facility (100) as claimed in claim 4, wherein the pop-up/pop-out infrastructure (171) comprises one or more roll-out canopies (114) to protect from an external physical environment.

6. The self-contained, integrated facility (100) as claimed in claim 1, wherein the pop-up enclosures (119) protect from the external physical environment and provide privacy.

7. The self-contained, integrated facility (100) as claimed in claim 1, wherein the pop-up enclosures (119) enclose a portable air exhaust system (163) to remove excess heat, fumes, and dust from the pop-up enclosures (119).

8. The self-contained, integrated facility (100) as claimed in claim 1, wherein the pop-up enclosures (119) enclose a privacy mesh (170) to allow privacy during transactions is placed over openings of a pop-up enclosure (119) to obscure movement and activity inside the pop-up enclosure (119).

9. The self-contained, integrated facility (100) as claimed in claim 8, wherein the privacy mesh (170) is placed over openings of the pop-up enclosure (119) to obscure movement and activity inside the pop-up enclosure (119).

10. The self-contained, integrated facility (100) as claimed in claim 1, wherein the pop-up enclosures (119) enclose a portable HVAC (144) to maintain a suitable environment for one or more operators (213) and equipment.

11. The self-contained, integrated facility (100) as claimed in claim 1, wherein the pull-out counter (109) extends from the central compartment (125) through one or more open rear cabinet doors (120) and an open tailgate (122).

12. The self-contained, integrated facility (100) as claimed in claim 1, wherein the communication and electronics compartment (111) operate synchronously for continuously connected environments whether to a local and distributed data ecosystem (208) or other network infrastructure or to operate asynchronously for non-continuous connected environments.

13. The self-contained, integrated facility (100) as claimed in claim 1, wherein the capital comprises tangible capital; and intangible capital.

14. The self-contained, integrated facility (100) as claimed in claim 1, wherein the pull-out counter (109) conducts a plurality of activities comprising transactions and sampling a natural capital.

15. The self-contained, integrated facility (100) as claimed in claim 1, wherein the mobile operation (200) functions as or as a part of a distributed data ecosystem (208).
